(19) United States
(12) Patent Application Publication
(10) Pub. No.: US 2006/0197203 A1
(43) Pub. Date: Sep. 7, 2006

(54) Die structure of package and method of manufacturing the same

(75) Inventors: Ching-Sung Chu, Kaohsiung County (TW); Tsung-Ta Tsai, Kaohsiung (TW); Ming-Yu Huang, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/320,635

(22) Filed: Dec. 30, 2005

(30) Foreign Application Priority Data
Mar. 3, 2005 (TW) 94106501

(51) Int. Cl. H01L 23/02

(52) U.S. Cl. 257/678

(57) ABSTRACT

A die structure of a package is provided. The die structure of the package includes a carrier and a die. The die includes a first portion and a second portion. The top surface of the first portion is an active surface. The second portion is configured below the first portion. A first width of the first portion is smaller than a second width of the second portion. And the second portion of the die is adhered to the carrier.

This application claims the benefit of Taiwan application Serial No. 94106501, filed Mar. 3, 2005, the subject matter of which is incorporated herein by reference.

### BACKGROUND OF THE INVENTION

1. Field of the Invention

The invention relates in general to a die structure of a package and a manufacturing method of the same, and more particularly to a die structure of a package capable of increasing the yield rate of the package and a manufacturing method of the same.

2. Description of the Related Art

Recently, the demand of high density and high output/input semi-conductive packages increases gradually with the trend of electronic products toward light weight, small size, multi-function and high speed. Therefore, a die in the package is becoming thinner and thinner to reduce the size of the whole package effectively.

A conventional wafer is separated into several dies after sawed. The conventional wafer is usually sawed by the method of wafer mount. That is to say, a back of the wafer is adhered to a tape and then is sawed by a sawing machine. After sawed, the dies are arranged on the tape so that they can easily be transported. Please referring to FIG. 1, a conventional sawed wafer is illustrated. In the process of sawing, the wafer is generally sawed through by a cutter 1 directly to separate the wafer into several dies 10. The thickness of the cutter 1 is generally about 1.0˜1.2 mils (40˜48 μm).

The separated die has to be electrically connected to a substrate of the package to be functional. At present, there are three electrical connecting methods: wire-bonding, tape automated bonding (TAB) and flip chip (FC). The wire-bonding method is easy and convenient to apply to new processes, and the techniques and machines of the wire-bonding method are developed sufficiently. Moreover, the automation and the wiring speed of the wire-bonding method make great progress recently. Therefore, the wire-bonding method is still the main technology in the market now.

FIG. 2 illustrates a conventional package with the wire-bonding. First, a separated die 10 is attached to a proper carrier 21, such as a substrate or a lead frame. For example, the dies 10 can be attached to the carrier 21 by a polymer adhesive, soft solder, or eutectic alloy. The attaching material is decided by factors such as the demand of hermetic sealing, the ability of dissipating heat and the coefficient of thermal expansion. The attaching material is usually Au—Si eutectic alloy, Au—Sn eutectic alloy, or epoxy adhesive with Ag. Then, a pad of the die 10 is electrically connected to a circuit of the substrate 21 by a thin metal wire 24. The connecting step usually can be completed by hot press, ultrasonic or both. The material of the metal wire is mainly aluminum or gold. The diameter of the metal wire is usually about 18˜75 μm. Afterwards, the die 10 with the wire 24 is encapsulated by a molding compound 26 for avoiding moisture to invade the package 2 and for protecting the whole package 2.

In general, when the thickness of the die is more than 3 mils (120 μm), the die is usually adhered to the carrier by epoxy 22 in the process of die attaching. However, when the die is adhered, the epoxy 22 is not solid. Therefore, a fillet height of the epoxy 22 must be controlled. If the fillet height of the epoxy 22 is not controlled properly, the epoxy 22 may cover part of an active surface 101 of the die 10 and contact the circuit of the active surface 101. As a result, a short circuit occurs.

Therefore, how to control the fillet height of the epoxy or other adhesives not to pass over the die and not to contact the active surface of the die is an important issue to increase the yield rate of the package.

### SUMMARY OF THE INVENTION

It is therefore an object of the invention to provide a die structure of a package and a manufacturing method of the same capable of increasing the field rate of the package. At least one concave is formed on a side of an active surface of the die to avoid epoxy or other adhesives to contact the active surface in the process of die attaching, so that the circuit connection of the die is not effected.

The invention achieves the above-identified objects by providing a die structure of a package at least including a carrier and a die. The die has an active surface and a bottom face. A first width of the active surface is smaller than a second width of the bottom surface. And the bottom surface of the die is adhered to the carrier.

The invention achieves the above-identified objects by providing a sawing method of a wafer including following steps. First, a wafer is provided. An active surface of the wafer has several cuttings. Then, the cuttings of the wafer are sawed by a first cutter to generate a first cutting depth. Next, the first cutting depth is sawed by a second cutter to generate a second cutting depth. The first cutting depth and the second depth are sawed through the wafer to obtain several separated dies. A first width of the first cutter is larger than a second width of the second cutter.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) illustrates a conventional sawed wafer;

FIG. 2 (Prior Art) illustrates a conventional package with wire-bonding;

FIG. 3 illustrates a die structure according to a preferable embodiment of the invention;

FIGS. 4A˜4C illustrate a method of sawing a wafer according to a preferable embodiment of the invention; and

FIG. 5 illustrates a package with wire bonding according to a preferable embodiment of the invention.

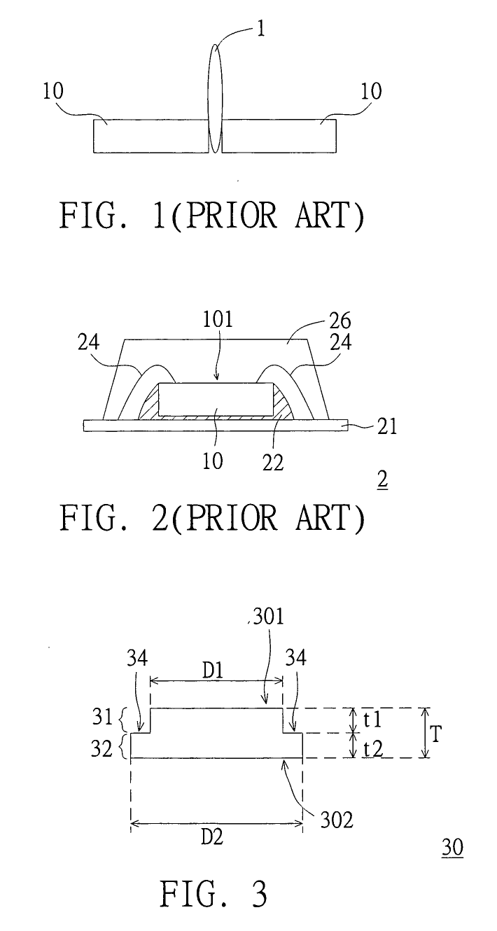

### DETAILED DESCRIPTION OF THE INVENTION

A die structure and a package having the die structure are provided in the invention. A fillet height of an epoxy or other adhesives is controlled by the die structure to increase the yield rate of the package.

Please referring to FIG. 3, a die structure according to a preferable embodiment of the invention is illustrated. The die 30 includes a first portion 31 and a second portion 32. The second portion 32 is configured below the first portion 31. The top of the first portion 31 is an active surface 301, and the bottom of the second portion 32 is a bottom surface 302. A first width D1 of the first portion 31 is smaller than a second width D2 of the second portion 32. The first portion 31 has a first thickness t1. The second portion 32 has a second thickness t2. The sum of the first thickness t1 and the second thickness t2 is equal to a total thickness T of the die 30. The second thickness t2 is preferably one to two times of the first thickness t1.

There is a concave 34 respectively on both side of the active surface 301 of the die 30. The design of the concave 34 can increase the path and difficulty of the epoxy or other adhesives to reach the active surface 301 of the die 30. Therefore, the fillet height can be controlled, and the probability that the epoxy or other adhesives reach the active surface 301 is decreased.

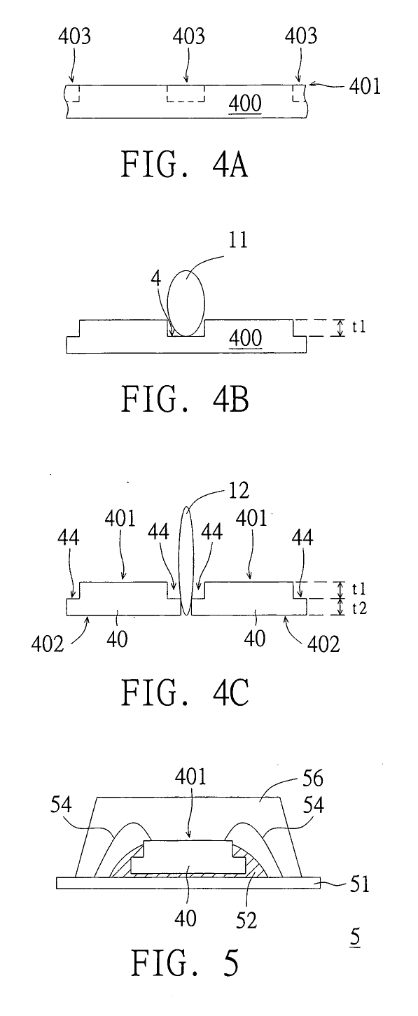

A method of manufacturing the structure of the die 30 is provided as follows. Please referring FIGS. 4A˜4C, a method of sawing a wafer according to a preferable embodiment of the invention is illustrated. First, a wafer 400 is provided. Several cuttings 403 are defined on an active surface 401 of the wafer 400, as shown in FIG. 4A. Then, the cuttings 403 of the wafer 400 are sawed by a first cutter 11 to generate a first cutting depth (equivalent to the first thickness t1 of the first portion 31 in FIG. 3), as shown in FIG. 4B. Next, the first cutting depth is continuously sawed by a second cutter 12 to generate a second cutting depth (equivalent to the second thickness t2 of the second portion 32 in FIG. 3). The first cutting depth and the second cutting depth are sawed through the wafer 400 to obtain several separated dies 40.

The first cutter 11 is wider than the second cutter 12. In an embodiment of the invention, the first width of the first cutter 11 is about 1.4 mil (56 μm). The second width of the second cutter 12 is about 0.8 mil (32 μm). Moreover, the first cutting depth is one-third to half of the total thickness T of the wafer 400. The first cutting depth is preferably not over half of the total thickness T of the wafer 400.

According to the above-described sawing method, a concave 44 can be formed on both side of the active surface 401 of the die 40 to achieve the goal of controlling the fillet height of the epoxy or other adhesives.

A die structure according to an embodiment of the invention is provided as follows. The die structure is illustrated as being electrically connected by the method of wire bonding.

Please referring to FIG. 5, a package with wire bonding according to a preferable embodiment of the invention is illustrated. First, a separated die 40 is attached to a proper carrier 51, such as a substrate or a lead frame. The die attaching step can be completed by using a polymer adhesive, soft solder or eutectic alloy. And the die attaching step is decided depending on factors such as the demand of hermetic sealing, the ability of dissipating heat and the coefficient of thermal expansion (CTE). In the present embodiment of the invention, the die 40 is adhered to the carrier 51 by an epoxy 52. Then, a contact pad of the active surface 401 of the die 40 is electrically connected to a circuit on the carrier 51 by a thin metal wire 54. The connecting step is usually completed by hot press, ultrasonic or both. The material of the metal wire 54 is mainly aluminum or gold. The diameter of the metal wire is about 18-75 μm. Afterwards, the die 40 with the wire 54 is encapsulated by a molding compound 56 to avoid moisture to invade the package 5 and to protect the whole package 5.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A die structure of a package, comprising:
a carrier; and
a die, comprising:
a first portion, wherein a top surface of the first portion is an active surface; and
a second portion configured below the first portion, wherein a first width of the first portion is smaller than a second width of the second portion;
wherein the second portion of the die is adhered to the carrier.

2. The die structure of the package according to claim 1, further comprising a plurality of wires electrically connected to the active surface and the carrier.

3. The die structure of the package according to claim 1, wherein the first portion has a first thickness, and the second portion has a second thickness, wherein the sum of the first thickness and the second thickness is equal to a total thickness of the die, and the second thickness is one to two times of the first thickness.

4. The die structure of the package according to claim 1, wherein the die is adhered to the carrier by an epoxy, and a fillet height of the epoxy is not more than a total thickness of the die.

5. A package, comprising:
a carrier;
a die comprising:
a first potion, wherein the top surface of the first portion is an active surface; and
a second portion configured below the first portion and adhered to the carrier, wherein a first width of the first portion is smaller than a second width of the second portion;
a plurality of wires electrically connected to the active surface of the die and the carrier; and
a molding compound for covering the die, the wires and part of the carrier.

6. The package according to claim 5, wherein the first portion of the die has a first thickness, and the second portion has a second thickness; wherein the second thickness is one to two times of the first thickness.

7. The package according to claim 6, wherein the second portion of the die is adhered to the carrier by an adhesive.

8. The package according to claim 7, wherein the sum of the first thickness and the second thickness is equal to a total thickness of the die, and a fillet height of the adhesive is not more than the total thickness of the die.

9. The package according to claim 8, wherein the adhesive is epoxy.
